(19) United States
(12) Patent Application Publication
(10) Pub. No.: US 2009/0306912 A1
(43) Pub. Date: Dec. 10, 2009

(54) METHOD OF MEASURING LED JUNCTION TEMPERATURE

(76) Inventors: JYH-CHEN CHEN, Jhongli City (TW); FARN-SHIUN HWU, Yangmei Township (TW); GWO-JIUN SHEU, Tainan City (TW); KUAN-CHIEH CHEN, Taipei City (TW); FENG-LONG LIN, Sanchong City (TW)

Correspondence Address: SINORICA, LLC, 2275 Research Blvd., Suite 500, ROCKVILLE, MD, 20850, US

(21) Appl. No.: 12/194,591

(22) Filed: Aug. 20, 2008

(30) Foreign Application Priority Data
Jun. 6, 2008 (TW) 97121281

(51) Int. Cl. G06F 19/00; H01L 21/66

(52) U.S. Cl. 702/57; 374/178; 257/E21.53

(57) ABSTRACT

A method of measuring LED junction temperature includes the steps of: (a) obtaining a temperature curve of an LED; (b) inputting at least one rated AC voltage to the LED; (c) measuring a temperature at a specific point on an outer packaging structure of the LED, putting the temperature measured at the specific point into the temperature curve, and calculating a junction temperature of the LED by interpolation; and (d) substituting the result from the calculation in the step (c) into a numerical analysis model to obtain temperature oscillation of the LED.

### FIELD OF THE INVENTION

The present invention relates to a method of measuring junction temperature, and more particularly to a method of measuring the junction temperature of a light-emitting diode (LED).

### BACKGROUND OF THE INVENTION

Due to the physical characteristics thereof, the light emitting diode (LED) has always been driven using direct current (DC). Since DC has stable voltage and linear change in forward bias voltage dependent upon temperature, the currently available methods for measuring LED junction temperature and thermal resistance are usually developed based on this linear characteristic.

In a general measuring method, the LED is first heated to find out a specific K value thereof, and a power supply is used to supply a testing current to the LED for measuring a voltage value V_{F1}. The testing current is then increased for the LED to emit light until a working temperature is reached and maintained over a period of time. Then, the testing current is decreased to the initial testing level again. At this point, another voltage value V_{F2} is measured, and a difference ΔV_{F} between V_{F1} and V_{F2} can be derived. Then, the above-mentioned K value is multiplied by ΔV_{F} to obtain a temperature variation ΔTj, and then the temperature variation ΔTj is added with the temperature of the LED before being supplied with the current to obtain the junction temperature Tj of the LED after being supplied with the current.

However, the above described method could only be used to measure the junction temperature of a DC LED. This is because, in an LED driven by alternating current (AC LED), the alternating current provides time-varied positive voltage and negative voltage, and the positive and negative voltage values must be higher than a starting voltage of the LED for the AC LED to emit light. According to the characteristics of alternating current, during the cyclic voltage change, the positive and negative voltage might be higher than the starting voltage in some time periods and lower in other time periods. Generally, a rated AC voltage Vrms is set as the starting voltage of an AC LED. During the voltage change cycle of the AC LED, the value of Vrms would rise to Vp and then lowers to Vrms again. Therefore, the existing methods for measuring the LED junction temperature are not suitable for use with AC voltage having a sinusoidal change.

### SUMMARY OF THE INVENTION

Therefore, one of objectives of the present invention is to provide a method of measuring LED junction temperature, so as to solve the problem of unable to measure the junction temperature of an LED driven by alternating current (AC) as found in the prior art.

The method of measuring LED junction temperature provided by the present invention is applicable to an AC LED. In the method of the present invention, the currently available method for measuring a DC LED is used to measure the junction temperature of an AC LED being supplied with a direct current (DC) and the temperature at a specific point on an outer packaging structure of the AC LED; and results from the above measuring are used to plot a temperature curve. Then, an alternating current is supplied to the AC LED, and the temperature at the specific point is calculated by interpolation to obtain the junction temperature of the AC LED.

The junction temperature of the AC LED is substituted into a numerical analysis model. Through the analysis conducted based on the numerical analysis model, it may be found the junction temperature of the AC LED is not constant. With the method of the present invention, it is able to further calculate the oscillation of the AC LED junction temperature within a certain temperature region. With the results from the numerical analysis model and the junction temperature calculated by interpolation, the junction temperature of the AC LED may be more accurately derived.

### BRIEF DESCRIPTION OF THE DRAWINGS

The subject matter regarded as the invention is particularly pointed out and distinctly claimed in the concluding portion of the specification. The invention together with features and advantages thereof may best be understood by reference to the following detailed description with the accompanying drawings in which:

FIG. 1 is a DC I-V curve plotted according to an LED junction temperature measuring method of the present invention;

FIG. 2 shows temperature corresponding curves plotted according to the LED junction temperature measuring method of the present invention;

FIG. 3 shows a crystal bar thermal field distribution obtained according to the LED junction temperature measuring method of the present invention;

FIG. 4 is a chip junction temperature oscillation graph obtained according to the LED junction temperature measuring method of the present invention; and

FIG. 5 is a flowchart showing the steps included in the method of measuring LED junction temperature according to the present invention.

### DETAILED DESCRIPTION OF THE PREFERRED EMBODIMENTS

A method of measuring LED junction temperature according to a preferred embodiment of the present invention will now be described with reference to the accompanying drawings. To enable easy understanding, parts and elements that are the same in the illustrated embodiment and drawings are denoted by the same reference numeral.

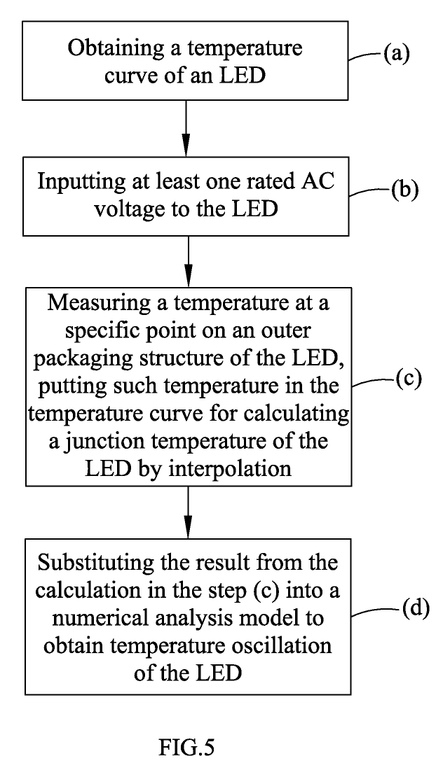

The present invention provides a method of measuring LED junction temperature, which is applicable to an AC LED, a K value of which is already known. In the present invention, a DC voltage source and a data acquisition card (DAQ card) are used to measure a junction temperature of the above-mentioned AC LED and a temperature at a specific point on a packaging structure of the AC LED. Please refer to FIG. 5. The method of the present invention includes the following steps:

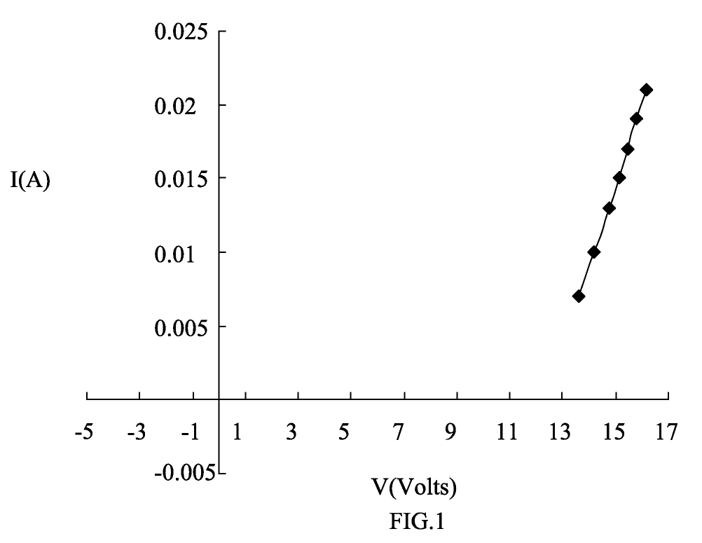

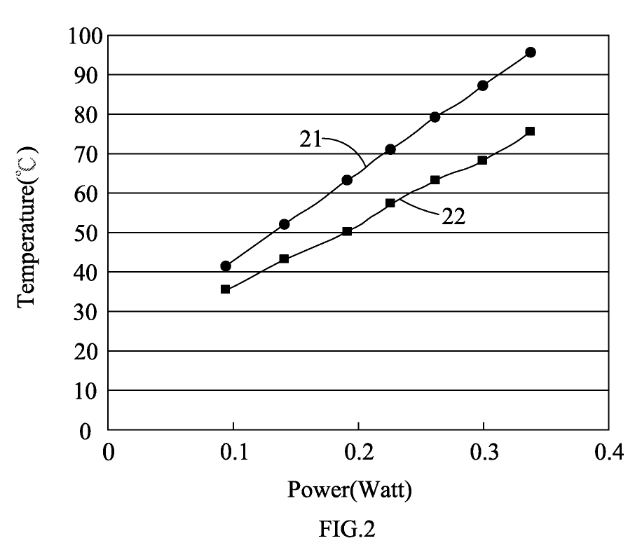

In step (a), a plurality of working currents is input to the AC LED, and then, the junction temperature and the temperature at a specific point on the packaging structure of the AC LED are measured. For example, seven different working currents, say, 7 mA, 10 mA, 13 mA, 15 mA, 17 mA, 19 mA, and 21 mA, are separately input to the AC LED, and voltage values corresponding to these working currents can be measured, as shown in FIG. 1. With the currents and the voltages are known, the electric power of the AC LED is measure, and the junction temperature of the AC LED as well as the temperature at the specific point on the packaging structure of the AC LED under each different input working current are measured. Temperature curves can be obtained based on the measured electric powers, junction temperatures, and temperatures at the specific point, as shown in FIG. 2. The temperature curve 21 is a junction temperature vs. electric power curve, and the temperature curve 22 is a specific packaging point temperature vs. electric power curve. Since the measuring of the AC LED junction temperature and the temperature at the specific point on the packaging of the AC LED, as well as the plotting of the temperature curves are known to a person of ordinary skill in the art, they are not described in details herein.

In step (b), a rated AC voltage Vrms is input to drive the AC LED. For example, the input rated AC voltage Vrms can be 12.2V. In step (c), the temperature at the specific point on the outer packaging structure of the above-mentioned AC LED is measured, and the temperature measured at the specific point on the packaging is put in the temperature curve plotted in the step (a), and the junction temperature of the AC LED is calculated by interpolation based on the temperature curve 21. In this step, by using the waveform of the electric power to calculate an average energy through integration and following the law of conservation of energy, it is able to prove the junction temperature derived from the interpolation is a reasonable value.

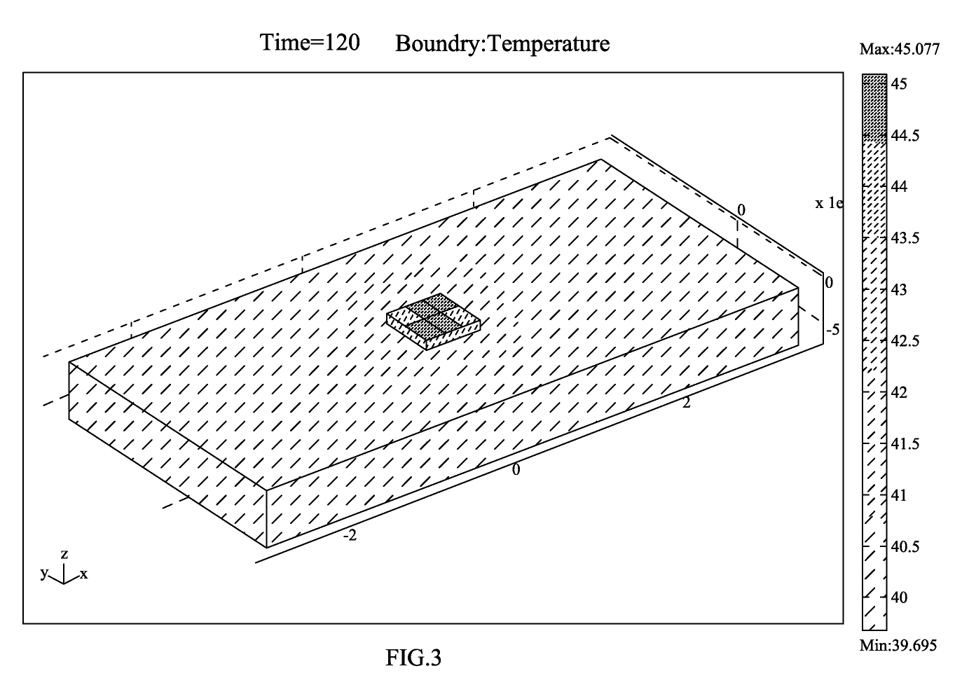

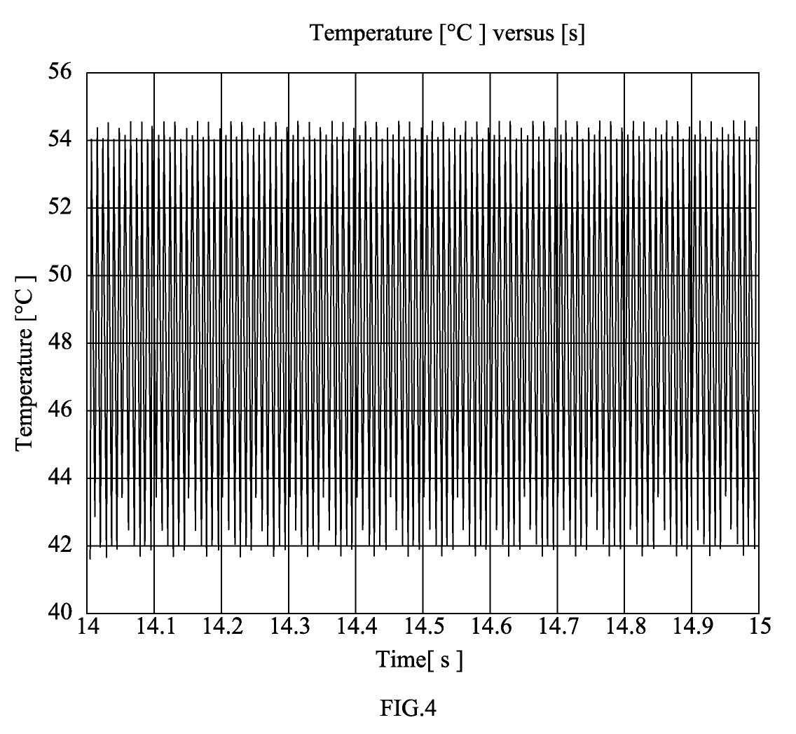

In step (d), the result from the calculation in the step (c) is substituted into a numerical analysis model as shown in FIG. 3. From this numerical analysis model, the state of temperature oscillation of the AC LED can be obtained, as shown in FIG. 4. The result from the calculation in the step (c) is used as a parameter of the numerical analysis model. Preferably, the numerical analysis model is a three-dimensional numerical analysis model for analyzing the AC LED and changes in the temperature at the specific point. The temperature region with oscillation that is obtained in the step (d) could not be measured in experiments using the currently available techniques. Moreover, the numerical analysis model employed in the present invention may also be used in the design of chip structure and packaging structure for the AC LED.

While the invention has been described by way of example and in terms of a preferred embodiment, it is to be understood that the invention is not limited thereto. To the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method of measuring LED junction temperature, comprising the following steps of:
(a) Obtaining a temperature curve of an LED;
(b) Inputting at least one rated AC voltage to the LED;
(c) Measuring a temperature at a specific point on an outer packaging structure of the LED, putting the temperature measured at the specific point in the temperature curve, and calculating a junction temperature of the LED by interpolation based on the temperature curve; and
(d) Substituting the result from the calculation in the step (c) into a numerical analysis model to obtain temperature oscillation of the LED.

2. The method of measuring LED junction temperature as claimed in claim 1, wherein the LED is an AC LED.

3. The method of measuring LED junction temperature as claimed in claim 1, wherein the temperature curve is generated by measuring the LED under a DC forward bias voltage and the temperature at the specific point.

4. The method of measuring LED junction temperature as claimed in claim 1, wherein the result from the calculation in the step (c) is used as a parameter of the numerical analysis model.

5. The method of measuring LED junction temperature as claimed in claim 1, wherein the numerical analysis model is a three-dimensional numerical analysis model.

6. The method of measuring LED junction temperature as claimed in claim 5, wherein the three-dimensional numerical analysis model is used to analyze the LED and changes in the temperature at the specific point.
